(19) United States
(12) Patent Application Publication
(10) Pub. No.: US 2015/0243926 A1
(43) Pub. Date: Aug. 27, 2015

(54) AMOLED PANEL AND METHOD OF ENCAPSULATING THE SAME

(71) Applicant: EverDisplay Optronics (Shanghai) Limited, Shanghai (CN)

(72) Inventors: Syue-Yi Deng, Shanghai (CN); Hongfeng Zhai, Shanghai (CN); Yenlong Wang, Shanghai (CN); Po Chun Hsieh, Shanghai (CN)

(21) Appl. No.: 14/624,953

(22) Filed: Feb. 18, 2015

(30) Foreign Application Priority Data
Feb. 24, 2014 (CN) 201410062714.5

(51) Int. Cl. H01L 51/52; H01L 51/00; H01L 27/32; H01L 51/56

(52) U.S. Cl. CPC H01L 51/5246; H01L 51/56; H01L 51/5243; H01L 51/0096; H01L 27/3244; H01L 2251/558; H01L 2227/323

(57) ABSTRACT

The embodiments of the present disclosure provide an AMOLED panel and method of encapsulating the same. The AMOLED panel comprises: a substrate; a plurality of TFTs arranged on the substrate spaced from each other; a cover, at a surface towards the substrate, the cover is provided with recesses corresponding to the plurality of TFTs and spacing parts formed between recesses; the cover covers on the substrate and TFTs; each TFT is received in each recess correspondingly, and the spacing parts are positioned between neighboring TFTs respectively; and a sealing layer connecting the spacing parts to the substrate. The present disclosure facilitates to control the flatness of the AMOLED panel.

### CROSS REFERENCE TO RELATED APPLICATIONS

This application claims the priority to and the benefit of Chinese Patent Application No. 201410062714.5, filed Feb. 24, 2014 and entitled “AMOLED panel and method of encapsulating the same,” which is incorporated herein by reference in its entirety.

### TECHNICAL FIELD

The present disclosure relates generally to the technical field of manufacturing semiconductor device, particularly to AMOLED panel and method of encapsulating the same.

### BACKGROUND

In current years, an organic Electro Luminescence (hereafter referred to “EL”) display device using organic EL assembly has replaced CRT and LCD display devices, thus being caught the attention. It is presently developing an organic EL display device having Thin Film Transistor (hereafter referred to “TFT”) for driving such as organic EL assembly.

Organic EL assembly (i.e. Organic Light-Emitting Diode, OLED) is formed layer by layer in order, in particular comprising: an anode formed by transparent electrode, such as Indium Tin Oxide (ITO) or the like; a hole transport layer composed of a first hole transport layer including MTDATA (4,4-bis(3-methylphenylphenylamino) Biphenyl) or the like and a second hole transport layer including TPD (4,4,4-ter (3-methylphenylphenylamino)Triphenylamine) or the like; a light emitting layer formed by Bebq2 (10-benzo[h]quinolinol-beryllium complex) including derivatives of Quinacridone; electronic transport layer formed by Bebq2; and a cathode formed by aluminum alloy.

The above organic EL assembly emits lights by current applied by TFT which is used for driving the organic EL assembly. That is, the hole injected from the anode combines with the electron injected from cathode at the inner of the light emitting layer, which allows organic molecules used for forming the light emitting layer to be excited so as to generate exciton. During radiation and deactivation of the exciton, the light is emitted from the light emitting layer, and emitted to the exterior through transparent anode and insulating substrate such as glass substrate or the like, so as to emit light.

Panel of Active Matrix/Organic Light Emitting Diode (AMOLED) as a kind of Organic Light-Emitting Diode (OLED) is evaporated by material extremely sensitive to water and oxygen, which needs encapsulation with good sealing for the panel after evaporation. However, if an epoxy resin adhesive is used, since the obstructing capability thereof is poor, and a desiccant should be adhered internally, it will create difficulty for designing the AMOLED panel with top-emitting structure.

An encapsulation method in current trend is to adopt glass to manufacture encapsulation materials for adhering between two glasses. FIG. 1 is a longitudinal cross section view of an AMOLED panel according to prior art. In particular, the AMOLED panel 1 comprises a substrate 11, TFT 12, cover 13 and encapsulation material 14. The substrate 11 is used for carrying the TFT 12. As shown in FIG. 1, a plurality of TFTs 12 are arranged and fixed on the substrate 11. The cover 13 covers on the substrate 11 and TFT 12. The encapsulation materials 14 are provided between the cover 13 and the substrate 11, and are positioned between neighboring TFT 12 respectively. Preferably, the encapsulation materials 14 are made of glass material for prevent water and oxygen entering so as to play a function of sealing. The encapsulation materials are adhered between the substrate 11 and the cover 13 after three procedures including coating, baking and sintering. It is no need to add desiccant since the encapsulation materials 14 have good obstructing capability.

FIG. 2 is a longitudinal cross section view of an AMOLED panel according to prior art. The substrate 11 and the cover 13 adhere with each other under pressure, and the contact area of encapsulation adhesive adhered to the substrate is small, and the structure between the cover 13 and the substrate 11 is hollow, therefore, the adherence flatness is difficult to control. As shown in FIG. 2, the flatness of the adhered AMOLED panel 1 is poor, which effects subsequent procedures. Moreover, the current AMOLED panel 1 has a relative larger thickness.

### SUMMARY

In order to solve the problem in the prior art, one object of the present disclosure is to provide an AMOLED panel and method of encapsulating the same, which facilitate controlling the flatness of the AMOLED panel.

In one aspect, the present disclosure provides an AMOLED panel comprising:

a substrate;

a plurality of TFTs formed on the substrate spaced apart from each other;

a cover formed with a plurality of recesses corresponding to the TFTs and a plurality of spacing parts formed between the recesses at a surface towards the substrate; wherein the cover is disposed on the substrate in such a manner that the TFTs are received in the corresponding recesses, and the spacing parts are positioned between the neighboring TFTs respectively; and

a sealing layer connecting the spacing parts to the substrate.

In an embodiment, the sealing layer is formed by a laser absorbing material through laser sintering.

In an embodiment, the laser absorbing material is selected from a group consisting of Boron oxide, Aluminum oxide, Magnesium oxide, Calcium oxide, Barium oxide, Titanium oxide, Cerium oxide, Molybdenum oxide, Samarium oxide, Ytterbium oxide or Tin oxide.

In an embodiment, a longitudinal cross section of the recess is of a rectangle shape.

In an embodiment, the thickness of the sealing layer is smaller than or equal to 6 μm.

In an embodiment, the depth of the recess is smaller than or equal to 10 μm.

In an embodiment, the width of the spacing part is smaller than or equal to 3 mm.

In an embodiment, the cover and the substrate are made of glass.

In another aspect, a method of encapsulating an AMOLED panel is further provided, comprising the steps of:

providing a substrate on which a plurality of TFTs are formed spaced apart from each other;

coating sealing materials on a surface of a cover;

removing part of sealing materials coated on the surface of the cover, and forming recesses corresponding to the TFTs by etching portions of the cover where the sealing materials are removed, wherein, spacing parts are formed between the recesses;

adhering the cover onto the substrate, such that the TFTs are received in the corresponding recesses, and the spacing parts are positioned between the neighboring TFTs respectively; and

processing the sealing materials to connect the spacing parts and the substrate.

In an embodiment, the step of removing part of the sealing materials coated on the surface of the cover comprises:

coating photoresist over the sealing materials on the cover;

exposing and developing the photoresist by using a mask having a desired pattern;

etching the sealing materials exposed from the photoresist until the surface of the cover is exposed;

etching the exposed surface of the cover to form the recesses.

In an embodiment, the photoresist is positive photoresist.

In an embodiment, the sealing material is laser absorbing material, and the processing is laser sintering.

In an embodiment, the laser absorbing material is selected from a group consisting of Boron oxide, Aluminum oxide, Magnesium oxide, Calcium oxide, Barium oxide, Titanium oxide, Cerium oxide, Molybdenum oxide, Samarium oxide, Ytterbium oxide or Tin oxide.

In an embodiment, the laser sintering comprising:

after aligning the substrate with the cover, sintering the laser absorbing materials on the spacing parts by laser to form sealing layer along a predetermined sintering track, such that the spacing parts of the cover are fixedly connected to the substrate.

In an embodiment, before the process of exposing, developing and etching, the method further comprises a step of baking the sealing materials coating on the surface of the cover.

In an aspect, a method of encapsulating an AMOLED panel is provided, comprising the steps of:

coating sealing materials on a surface of a substrate;

removing parts of sealing materials coated on the surface of the substrate, wherein, the removed parts of the sealing materials are spaced apart from each other;

providing TFTs at positions of the substrate where the sealing materials are removed;

providing a cover, and forming recesses on the cover corresponding to the TFTs by etching, wherein, spacing parts are formed between recesses;

adhering the cover onto the substrate, such that the TFTs are received in the corresponding recesses, and the spacing parts are positioned between the neighboring TFTs respectively; and

processing the sealing materials to connect the spacing parts and the substrate.

In an embodiment, the sealing material is laser absorbing material, and the processing is laser sintering process.

In an embodiment, the laser sintering process comprising:

after aligning the substrate with the cover, sintering the laser absorbing material on the spacing parts by laser to form sealing layer along a predetermined sintering track, such that the spacing parts of the cover are fixedly connected to the substrate.

In the present disclosure the structure of the cover of the AMOLED panel is improved, that is, at a surface towards the substrate, the cover is provided with recesses corresponding to the TFT and spacing parts formed between neighboring recesses, and the sealing layer corresponding to spacing parts connects the cover to the substrate. The cover with the above structure adheres to the substrate, such that the contact area is large and flat, the adherence flatness is improved greatly, thusly providing great help to subsequent laser sintering process, and thinning the thickness of the product compared with that in the prior art. The AMOLED panel enhances the adherence flatness and improves adverse effects to laser sintering process.

Concerning the method of encapsulating an AMOLED panel as provided in the present disclosure, the cover is manufactured such as by semiconductor procedure including coating laser absorbing material as sealing layer by film process, gradually etching by cycle process of exposing, developing and etching, removing undesirable sealing layer and etching to form recesses corresponding to TFT; or forming a substrate having TFT and sealing layer and a cover having recesses and spacing parts by coating, exposing and developing at the substrate and cover respectively, and combining the substrate with the cover. The above encapsulation method has advantageous effects as follow:

1. it enhances the adherence flatness and improves adverse effects to laser sintering process.

2. the contact surface between the cover and the substrate is completely coated with the sealing layer such as laser absorbing material, which can be totally treated by laser sintering process. Such that if adjusting laser sintering position, it only needs to adjust laser track without changing the screen or the arrangement of adhesive, and if adjusting laser sintering width, it only needs to adjust the size of light spot without changing the screen or adhesive needle, moreover, compared with screen print or coating adhesive process, there is no variation problem of the difference between the distance between two points at the mask as designed and the distance between two points as measured at the substrate produced actually in one direction.

The foregoing summary is not intended to summarize each potential embodiment or every aspect of the present disclosure.

### BRIEF DESCRIPTION OF THE DRAWINGS

The accompanying drawings, which are incorporated in and constitute a part of this specification, illustrate embodiments consistent with the invention and, together with the description, serve to explain the principles of the invention.

FIG. 1 is a longitudinal cross section view of an AMOLED panel according to prior art which is in a disassemble state.

FIG. 2 is a longitudinal cross section view of an AMOLED panel according to prior art which is assembled by adhering.

FIG. 3 is a longitudinal cross section view of an AMOLED panel according to a first embodiment of the disclosure which is in a disassemble state.

FIG. 4 is a longitudinal cross section view of an AMOLED panel according to a first embodiment of the disclosure which is in a assemble state.

FIG. 5 is a flowchart of encapsulation method in embodiment 1 for the AMOLED panel as shown in FIG. 4 of the present disclosure.

FIG. 6 is a flowchart of steps of a cycle process of exposing, developing and etching in the encapsulation method as shown in FIG. 5.

FIG. 7 is a longitudinal cross section view of a cover coated with laser absorbing layer according to the present disclosure.

FIG. 8 is a longitudinal cross section view of a cover coated with photoresist according to the present disclosure.

FIG. 9 is a longitudinal cross section view of a cover after exposing, developing and etching process at the first time according to the present disclosure.

FIG. 10 is a longitudinal cross section view of a cover coated with photoresist again according to the present disclosure.

FIG. 11 is a longitudinal cross section view of a cover after exposing, developing and etching again according to the present disclosure.

FIG. 12 is a flowchart of steps of laser sintering in the encapsulation method as shown in FIG. 5.

FIG. 13 is a flowchart of encapsulation method in embodiment 2 for the AMOLED panel as shown in FIG. 4 of the present disclosure.

FIG. 14 is a flowchart of encapsulation method in embodiment 3 for the AMOLED panel as shown in FIG. 4 of the present disclosure.

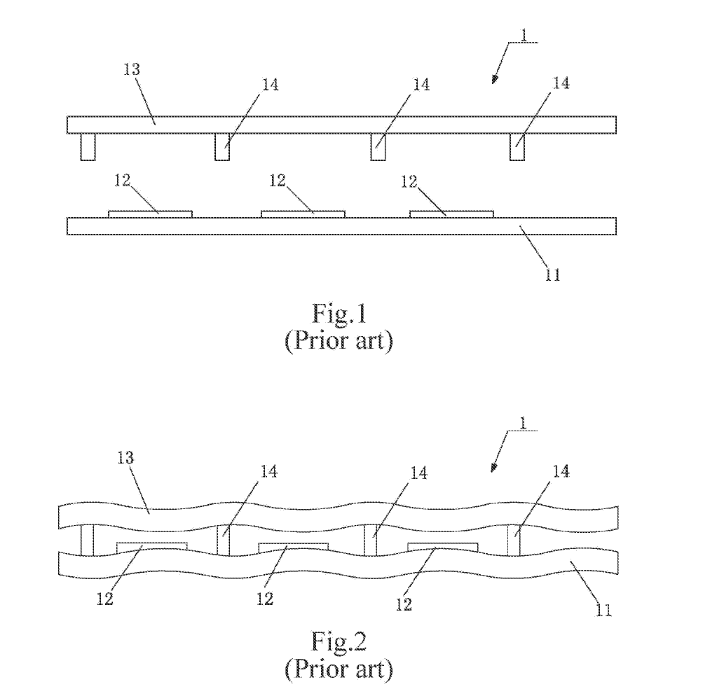

Specific embodiments in this disclosure have been shown by way of example in the foregoing drawings and are hereinafter described in detail. The figures and written description are not intended to limit the scope of the inventive concepts in any manner. Rather, they are provided to illustrate the inventive concepts to a person skilled in the art by reference to particular embodiments.

### DETAILED DESCRIPTION

Hereinafter, embodiments of the disclosure will be described in detail in conjunction with the drawings.

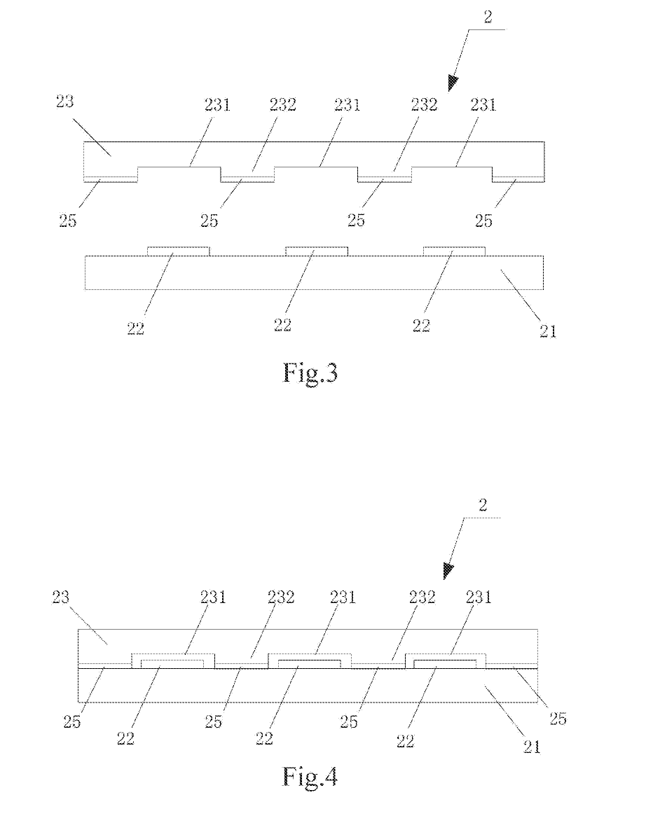

FIG. 3 is a longitudinal cross section view of an AMOLED panel according to a first embodiment of the disclosure which is in a disassemble state. FIG. 4 is a longitudinal cross section view of an AMOLED panel according to a first embodiment of the disclosure which is adhered. As shown in FIGS. 3 and 4, the AMOLED panel 2 comprises a substrate 21, a plurality of Thin Film Transistors (TFT) 22 and a cover 23. The substrate 21 is used for carrying the TFTs 22. Preferably, the substrate 21 is made of glass material. The plurality of TFTs 22 are arranged on the substrate 21 spaced from each other.

The cover 23 is adhered to the substrate 21 and the plurality of TFTs 22 and located above the substrate 21 and the TFTs 22. Preferably, the cover 23 is made of glass material. Further, at a surface towards the substrate, the cover 23 is provided with recesses 231 corresponding to the plurality of TFTs 22 and spacing parts 232 formed between recesses 231. Each TFT 22 is received in each recess 231 correspondingly, and the spacing parts 232 are positioned between neighboring TFTs 22 respectively. Preferably, the depth of each recess 231 is smaller than or equal to 10 μm. In case that the TFTs 22 are tightly arranged on the substrate 21, the distance between neighboring TFTs 22 (i.e. the width of the spacing part 232) is smaller than or equal to 3 mm.

In the preferable embodiment as shown in FIG. 3, the shape of a longitudinal cross section of each recess 231 at the cover 23 is rectangle, which is not limited thereto. For example, in a modified embodiment, the shape of a longitudinal cross section of each recess 231 may be square. In another modified embodiment, the shape of a longitudinal cross section of each recess 231 may also be semi-circle round. The person skilled in the art could understand that each modified embodiment is able to be realized, which will not be redundantly explained.

Moreover, as shown in FIG. 3, the AMOLED panel 2 further comprises a sealing layer 25 for connecting the spacing parts 232 to the substrate 21, which is formed through laser sintering process by a laser absorbing material between the spacing parts 232 and the substrate 21.

Preferably, the thickness of the sealing layer 25 is smaller than or equal to 6 μm. The sealing layer 25 is preferably manufactured of any laser absorbing material selected from Boron oxide, Aluminum oxide, Magnesium oxide, Calcium oxide, Barium oxide, Titanium oxide, Cerium oxide, Molybdenum oxide, Samarium oxide, Ytterbium oxide, Tin oxide or the like as sealing material.

In the first embodiment according to the AMOLED panel of the present disclosure, the encapsulation materials used as sealing structure in the prior art is replaced by the recesses 231 and spacing parts on the cover and the sealing layer 25 between the spacing parts 232 and the substrate 21, such that the hollow structure between the substrate and the cover is avoided, thusly enlarging the contact area between the substrate and the cover of the AMOLED panel after being adhered, greatly enhancing the flatness of the contact area, and reducing the thickness of the finished panel compared with that of the panel in the prior art.

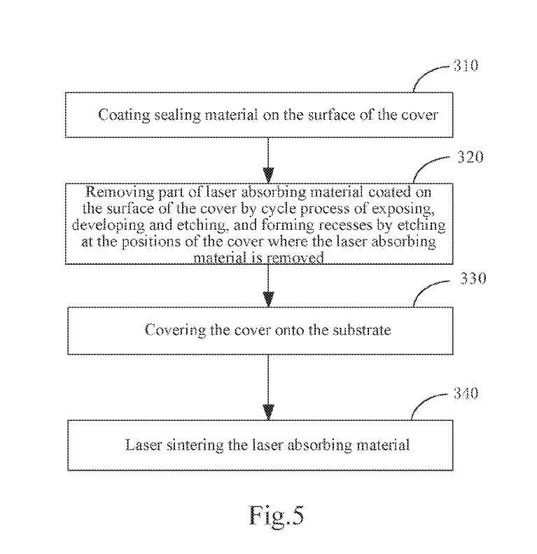

The method for encapsulating the AMOLED panel according to the present disclosure will be explained as follows referring to FIGS. 5 to 13.

FIG. 5 is a flowchart of encapsulation method in embodiment 1 for the AMOLED panel as shown in FIG. 4 of the present disclosure. In particular, the method for encapsulating the AMOLED panel 2 comprises:

Step 310: coating sealing material (such as laser absorbing material) on the surface of the cover. Preferably, the laser absorbing material may be any one from Boron oxide, Aluminum oxide, Magnesium oxide, Calcium oxide, Barium oxide, Titanium oxide, Cerium oxide, Molybdenum oxide, Samarium oxide, Ytterbium oxide, Tin oxide or the like. Preferably, the cover is made of glass material.

Step 320: removing part of laser absorbing material coated on the surface of the cover by exposing, developing and etching, and forming recesses by etching at the positions of the cover where the laser absorbing material is removed, thusly forming spacing parts between neighboring recesses, which still retain a layer of laser absorbing material thereon. The positions where part of laser absorbing material is removed are predetermined to be corresponding to the position where the TFTs are provided on the substrate (referring to the positions of TFTs 22 are shown in FIG. 3 or 4).

Step 330: covering the cover onto the substrate. Wherein, the substrate is provided with a plurality of TFTs spaced from each other. Each TFT is received in each recess correspondingly, and the spacing parts are positioned between neighboring TFTs respectively. Preferably, the substrate is made of glass material.

Step 340: sintering the laser absorbing material between the spacing parts and the substrate by laser (i.e. it is sealed the sealing material) so as to form a sealing portion for connecting the spacing parts of the cover to the substrate.

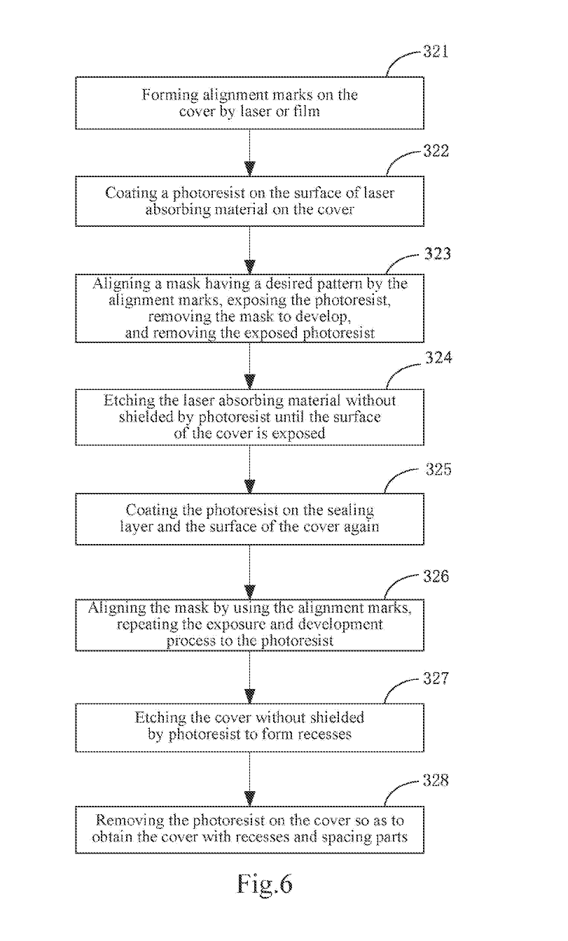

FIG. 6 is a flowchart of steps of a cycle process of exposing, developing and etching in the encapsulation method as shown in FIG. 5. In particular, steps of a cycle process of exposing, developing and etching in Step 320 comprises the sub-steps as follows:

Step 321: forming alignment marks on the cover by laser or film. The positions of the alignment marks are corresponding to the position of the TFTs on the substrate.

Step 322: coating the photoresist on the surface of laser absorbing material on the cover.

Step 323: aligning a mask having a desired pattern by the alignment marks formed in Step 321, exposing the photoresist, removing the mask to develop, and removing the exposed photoresist.

Step 324: etching the laser absorbing material without shielded by photoresist until the surface of the cover is exposed.

Step 325: coating the photoresist on the sealing layer and the surface of the cover again.

Step 326: aligning the mask mentioned in Step 321 and 323, repeating the exposure and development process to the photoresist.

Step 327: etching the cover without shielded by photoresist to form recesses.

Step 328: removing the photoresist on the cover so as to obtain the cover with recesses and spacing parts, wherein, the spacing parts has laser absorbing material.

Furthermore, in a modified embodiment, the person skilled in the art could understand that during the cycle process of exposing, developing and etching, in case that the pattern of cover to be etched is in accordance with that of laser absorbing material to be etched, it is possible to omit the second exposure and development process in Steps 325 and 326, that is, to directly etch to the cover after etching and removing the laser absorbing material. The object of the second exposure and development process is to adjust the pattern of the recesses to be etched on the cover.

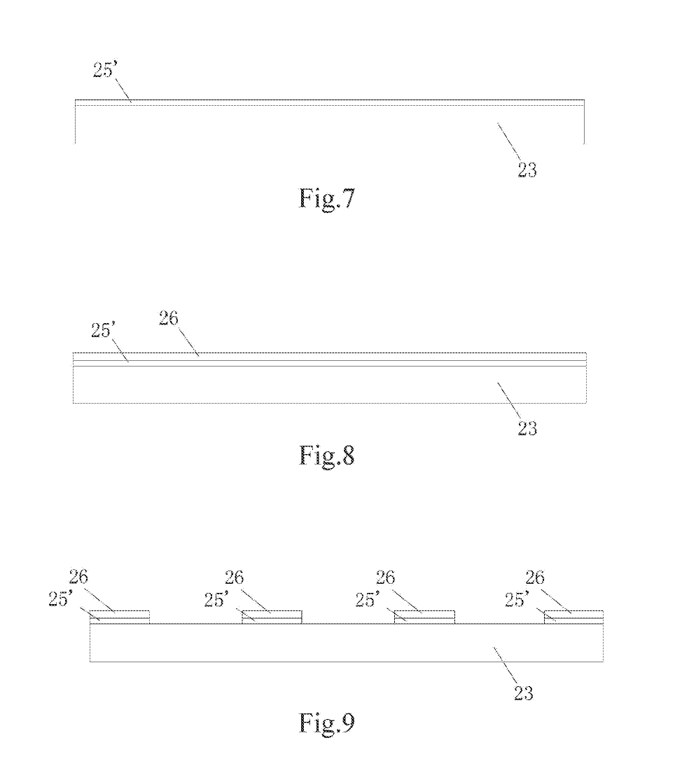

Hereinafter, the longitudinal cross section structure of cover which is corresponding to the primary steps in the above encapsulation method will be described in detail in conjunction with the FIGS. 7 to 11.

FIG. 7 is a longitudinal cross section view of a cover coated with laser absorbing layer, which is corresponding to Step 310 as shown in FIG. 5. In particular, as shown in FIG. 7, the laser absorbing material 25′ is completely coated on the surface of the cover 23 with a thickness smaller than or equal to 6 μm preferably.

FIG. 8 is a longitudinal cross section view of a cover coated with photoresist, which is corresponding to Step 322 as shown in FIG. 6. In particular, as shown in FIG. 8, after coating the laser absorbing material 25′ on the surface of the cover 23, completely coating photoresist 26 on the laser absorbing material 25′. Preferably, positive photoresist is used as photoresist 26.

FIG. 9 is a longitudinal cross section view of a cover after exposing, developing and etching at the first time, which is corresponding to Steps 323 and 324 as shown in FIG. 6. In particular, as shown in FIG. 9, after coating photoresist 26, aligning a mask on the cover 23 having the laser absorbing material 25′ and photoresist 26 by the alignment marks formed previously. The laser absorbing material 25′ is exposed after photoresist 26 without shielded by the mask is exposed and developed, and then, the exposed laser absorbing material 25′ is etched so as to obtain the cover 23 as shown in FIG. 9.

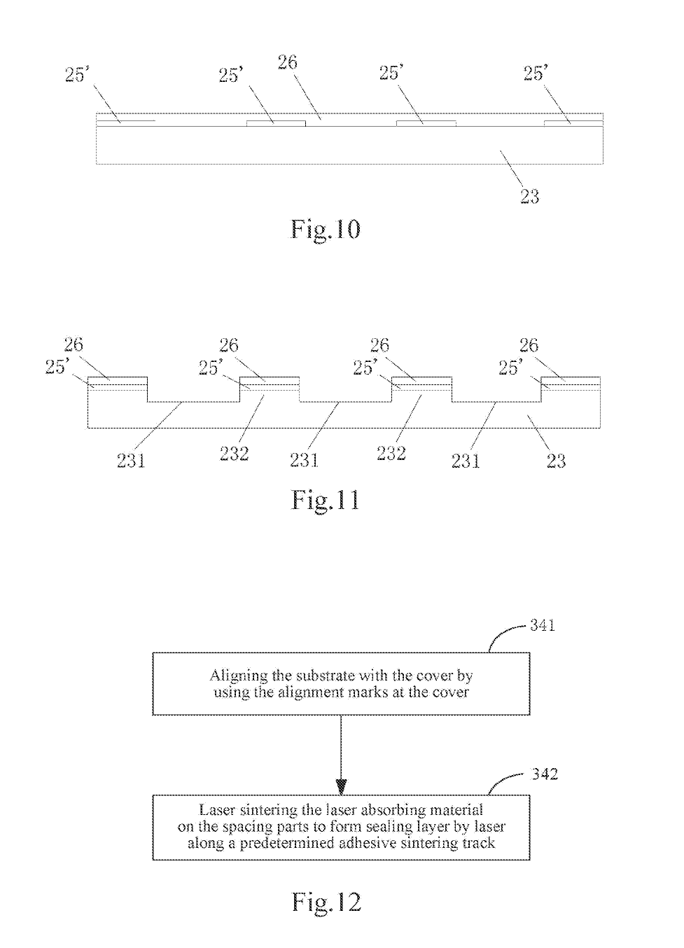

FIG. 10 is a longitudinal cross section view of a cover coated with photoresist again, which is corresponding to Step 325 as shown in FIG. 6. In particular, as shown in FIG. 10, after etching and removing part of laser absorbing material 25′, completely coating the photoresist 26 on the laser absorbing material 25′ and the surface of the cover 23 again. Preferably, positive photoresist is used as photoresist 26.

FIG. 11 is a longitudinal cross section view of a cover after exposing, developing and etching again, which is corresponding to Steps 326 and 327 as shown in FIG. 6. In particular, as shown in FIG. 11, aligning the mask used in the previous exposing and developing process again to expose, and then etching the cover 23 without shielded by photoresist to form recesses 231 and spacing parts 232, so as to obtain the cover 23 as shown in FIG. 11. Preferably, the depth of each recess 231 is smaller than or equal to 10 μm.

Placing the cover 23 with the photoresist 26 removed as shown in FIG. 11 on the substrate 21 carrying TFTs 22, and then sintering the laser absorbing material 25′ on the spacing part 232 of the cover 23 by laser so as to form a sealing layer 25, finally obtaining the AMOLED panel 2 as shown in FIG. 4. The laser absorbing material 25′ is completely coated between the spacing parts 232 and the substrate 21, therefore, the whole area coated with the laser absorbing material 25′ could be laser sintered, such that if adjusting laser sintering position, it only needs to adjust laser track without changing the screen or the arrangement of adhesive, and if adjusting laser sintering width, it only needs to adjust the size of light spot without changing the screen or adhesive needle, moreover, compared with screen print or coating adhesive process, there is no variation problem of the difference between the distance between two points at the mask as designed and the distance between two points as measured at the substrate produced actually in one direction.

FIG. 12 is a flowchart of steps of laser sintering in the encapsulation method as shown in FIG. 5. In particular, the Step 340 of laser sintering comprises the sub-steps as follows:

Step 341: aligning the substrate with the cover by using the alignment marks at the cover as mentioned before.

Step 342: laser sintering the laser absorbing material 25′ on the spacing parts to form sealing layer 25 by laser along a predetermined adhesive sintering track, the sealing layer 25 fixedly connects the spacing parts of the cover to the substrate so as to play a function of sealing the AMOLED panel.

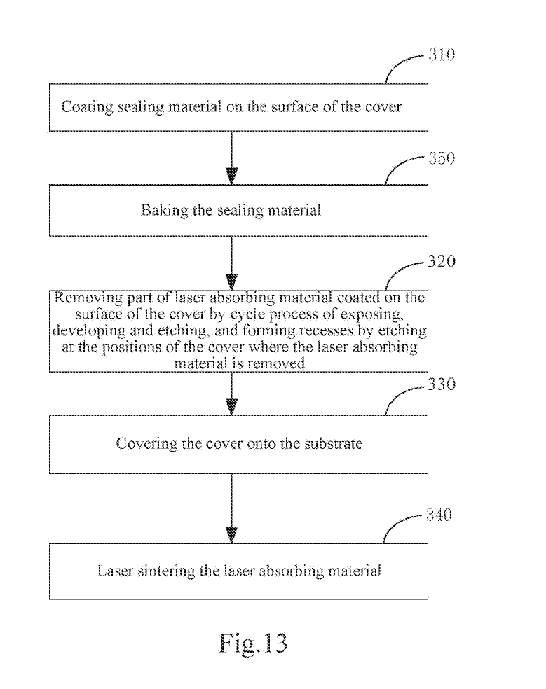

FIG. 13 is a flowchart of encapsulation method in embodiment 2 for the AMOLED panel as shown in FIG. 4 of the present disclosure, which may be explained as a modified embodiment compared with FIG. 5. In particular, compared with the encapsulation method as shown in FIG. 5, the difference is that the encapsulation method in embodiment 2 for the AMOLED panel 2 further comprises Step 350: baking the sealing material. The Step 350 is performed before Step 320 that cycle process of exposing, developing and etching. In particular, in order to uniformly coating, the sealing layer is commonly manufacture by liquid material mixed with solvent, therefore the step of baking the sealing layer plays function of drying and setting, such that the sealing layer can adhere to the surface of the cover much better.

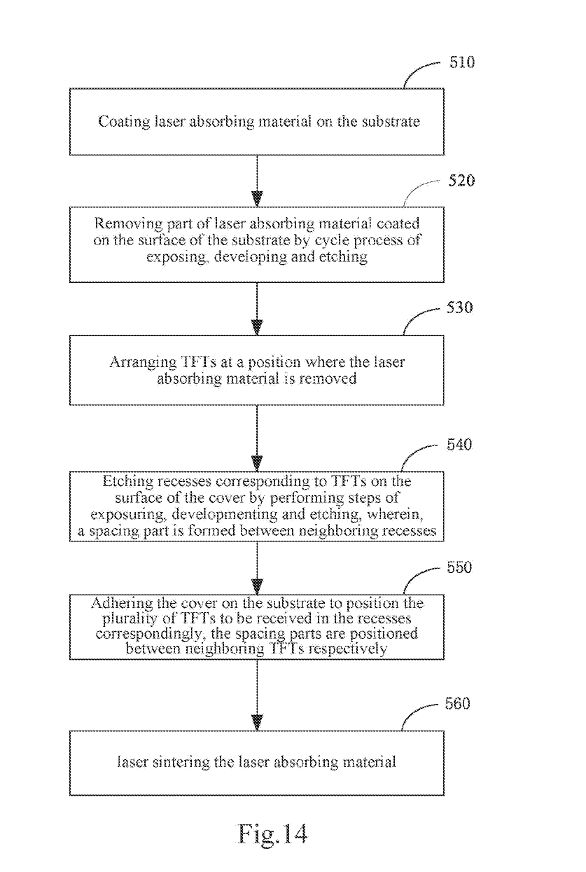

FIG. 14 is a flowchart of encapsulation method in embodiment 3 for the AMOLED panel as shown in FIG. 4 of the present disclosure. Compared with the encapsulation method 1 as shown in FIG. 5, the difference is that: in the encapsulation method 3 for the AMOLED panel, the laser absorbing layer used as encapsulating material is firstly coated on the substrate rather than cover. The encapsulation method 3 mainly comprises: Step 510: coating laser absorbing material on the substrate. Step 520: removing part of laser absorbing material on the surface of the substrate according to the required pattern by forming alignment marks, coating photoresist, exposuring, developmenting and etching or the like. Step 530: arranging TFTs at a position where the laser absorbing material is removed. Step 540: etching recesses corresponding to TFT on the surface of the cover by performing steps of exposuring, developmenting and etching, wherein, a spacing part is formed between neighboring recesses. Step 550: then adhering the cover on the substrate to position the plurality of TFTs to be received in the recesses correspondingly. The spacing parts are positioned between neighboring TFTs respectively. Step 560: performing a sealing process to the laser absorbing material so as to form the AMOLED panel having a structure identical with that in FIGS. 3 and 4. In the present embodiment, the sealing material is laser absorbing material, and the sealing process is laser sintering process which comprises the following steps: after aligning the substrate with the cover, sintering the laser absorbing material on the spacing parts by laser to form sealing layer by laser along a predetermined sintering track, such that the spacing parts of the cover fixedly connects to the substrate.

In conclusion, the person skilled in the art could understand, compared with the conventional technology, the AMOLED panel and method of encapsulating the same provided in the present disclosure may have one or more of the following technical effects:

1) the structure of the cover in the AMOLED panel is changed, which is manufactured such as by semiconductor procedure including coating laser absorbing material by film process, gradually etching by cycle process of exposing, developing and etching, removing undesirable laser absorbing material so as to form recesses corresponding to TFTs and spacing parts coated with laser absorbing material. The cover with the above structure adheres to the substrate, such that the contact area is large and flat, the adherence flatness is improved greatly, thusly providing great help to subsequent laser sintering process, and thinning the thickness of the product compared with that in the prior art. The AMOLED panel enhances the adherence flatness and improves adverse effects to laser sintering process.

2) the contact surface between the cover and the substrate is completely coated with the laser absorbing material, which can be totally treated by laser sintering process. Such that if adjusting laser sintering position, it only needs to adjust laser track without changing the screen or the arrangement of adhesive, and if adjusting laser sintering width, it only needs to adjust the size of light spot without changing the screen or adhesive needle, moreover, compared with screen print or coating adhesive process, there is no variation problem of the difference between the distance between two points at the mask as designed and the distance between two points as measured at the substrate produced actually in one direction.

It should be noted that the above embodiments are only illustrated for describing the technical solution of the disclosure and not restrictive, and although the embodiments are described in detail by referring to the aforesaid embodiments, the skilled in the art should understand that the aforesaid embodiments can be modified and portions of the technical features therein may be equally changed, which does not depart from the spirit and scope of the technical solution of the embodiments of the disclosure.

What is claimed is:

1. An AMOLED panel comprising:
a substrate;
a plurality of TFTs formed on the substrate spaced apart from each other;
a cover formed with a plurality of recesses corresponding to the TFTs and a plurality of spacing parts formed between the recesses at a surface towards the substrate; wherein the cover is disposed on the substrate in such a manner that the TFTs are received in the corresponding recesses, and the spacing parts are positioned between the neighboring TFTs respectively; and
a sealing layer connecting the spacing parts to the substrate.

2. The AMOLED panel according to claim 1, wherein the sealing layer is formed by a laser absorbing material through laser sintering.

3. The AMOLED panel according to claim 2, wherein the laser absorbing material is selected from a group consisting of Boron oxide, Aluminium oxide, Magnesium oxide, Calcium oxide, Barium oxide, Titanium oxide, Cerium oxide, Molybdenum oxide, Samarium oxide, Ytterbium oxide or Tin oxide.

4. The AMOLED panel according to claim 1, wherein a longitudinal cross section of the recess is of a rectangle shape.

5. The AMOLED panel according to claim 1, wherein the thickness of the sealing layer is smaller than or equal to 6 μm.

6. The AMOLED panel according to claim 5, wherein the depth of the recess is smaller than or equal to 10 μm.

7. The AMOLED panel according to claim 1, wherein the width of the spacing part is smaller than or equal to 3 mm.

8. The AMOLED panel according to claim 1, wherein the cover and the substrate are made of glass.

9. A method of encapsulating an AMOLED panel, comprising the steps of:
providing a substrate on which a plurality of TFTs are formed spaced apart from each other;
coating sealing materials on a surface of a cover;
removing part of the sealing materials coated on the surface of the cover, and forming recesses corresponding to the TFTs by etching portions of the cover where the sealing materials are removed, wherein, spacing parts are formed between the recesses;
adhering the cover onto the substrate, such that the TFTs are received in the corresponding recesses, and the spacing parts are positioned between the neighboring TFTs respectively; and
processing the sealing materials to connect the spacing parts and the substrate.

10. The method of encapsulating an AMOLED panel according to claim 9, wherein the step of removing part of the sealing materials coated on the surface of the cover comprises:
coating photoresist over the sealing materials on the cover;
exposing and developing the photoresist by using a mask having a desired pattern;
etching the sealing materials exposed from the photoresist until the surface of the cover is exposed; and
etching the exposed surface of the cover to form the recesses.

11. The method of encapsulating an AMOLED panel according to claim 10, wherein the photoresist is positive photoresist.

12. The method of encapsulating an AMOLED panel according to claim 9, wherein the sealing material is laser absorbing material, and the processing is laser sintering.

13. The method of encapsulating an AMOLED panel according to claim 12, wherein the laser absorbing material is selected from a group consisting of Boron oxide, Aluminum oxide, Magnesium oxide, Calcium oxide, Barium oxide, Titanium oxide, Cerium oxide, Molybdenum oxide, Samarium oxide, Ytterbium oxide or Tin oxide.

14. The method of encapsulating an AMOLED panel according to claim 12, wherein the laser sintering comprises:
after aligning the substrate with the cover, sintering the laser absorbing materials on the spacing parts by laser to form sealing layer along a predetermined sintering track, such that the spacing parts of the cover are fixedly connected to the substrate.

15. The method of encapsulating an AMOLED panel according to claim 10, before the steps of exposing, developing and etching, the method further comprising a step of baking the sealing materials coating on the surface of the cover.

16. A method of encapsulating an AMOLED panel, comprising the steps of:
coating sealing materials on a surface of a substrate;
removing parts of sealing materials coated on the surface of the substrate, wherein, the removed parts of the sealing materials are spaced apart from each other;
providing TFTs at positions of the substrate where the sealing materials are removed;
providing a cover, and forming recesses on the cover corresponding to the TFTs by etching, wherein, spacing parts are formed between recesses;
adhering the cover onto the substrate, such that the TFTs are received in the corresponding recesses, and the spacing parts are positioned between the neighboring TFTs respectively; and
processing the sealing materials to connect the spacing parts and the substrate.

17. The method of encapsulating an AMOLED panel according to claim 16, wherein the sealing material is laser absorbing material, and the processing is laser sintering process.

18. The method of encapsulating an AMOLED panel according to claim 17, wherein the laser sintering process comprising:
after aligning the substrate with the cover, sintering the laser absorbing material on the spacing parts by laser to form sealing layer along a predetermined sintering track, such that the spacing parts of the cover are fixedly connected to the substrate.
